(19) United States
(12) Patent Application Publication
(10) Pub. No.: US 2005/0090059 A1
(43) Pub. Date: Apr. 28, 2005

(54) Method for manufacturing a non-volatile memory device

(75) Inventors: Jung Hwan Lee, Chungcheongbuk-do (KR); Seo Yong Chi, Chungcheongbuk-do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/968,200

(22) Filed: Oct. 19, 2004

(30) Foreign Application Priority Data
Oct. 22, 2003 (KR) 2003-73987

(51) Int. Cl. H01L 21/336

(52) U.S. Cl. 438/257

(57) ABSTRACT

A method for manufacturing a non-volatile memory device which can increase the coupling ratio and can avoid affecting the height of a control gate by forming a trench in a cell region and forming a floating gate in a concave shape in the trench is disclosed. The method comprises: forming a first trench having a first depth on a silicon substrate of a peripheral circuit region, burying the same with a buried oxide film and planarizing the same; forming a second trench having a second depth on the silicon substrate of the cell region; carrying out channel ion implantation to the cell region, forming a tunnel oxide film in the second trench and depositing a floating gate material; forming a floating gate by etching the floating gate material; forming a source/drain junction in the cell region; forming wells in the peripheral circuit and cell regions and depositing a dielectric film; depositing a gate material while leaving the dielectric film only in the channel portion of the cell region; and forming a gate in the peripheral circuit region and a control gate in the cell region by etching the gate material.

### BACKGROUND OF THE INVENTION

1. Field of the Invention

The present invention relates to a method for manufacturing a non-volatile memory device, and more particularly, to a method for manufacturing a non-volatile memory device which avoids affecting the height of the control gate by forming a trench in a cell region, forming a floating gate in a concave shape in the trench and making a dielectric film to cover the floating gate.

2. Description of the Related Art

Non-volatile memory devices can retain their previous data even though their power supplies are interrupted. These non-volatile memory devices include EPROMs capable of being electrically programmed and erased through the irradiation of a UV light and EEPROMs capable of being electrically programmed and erased. Flash memories have a small chip size and excellent program and erase characteristics in the EEPROM.

The non-volatile memory device typically includes a floating gate capable of accumulating electric charges in a general MOS transistor structure. That is, in a flash memory device, a floating gate is formed on a semiconductor substrate through a thin gate oxide layer called a tunnel oxide layer and a control gate electrode is formed on an upper portion of the floating gate through a gate interlayer dielectric layer. Therefore, the floating gate is electrically insulated from the semiconductor substrate and the control gate electrode by the tunnel oxide layer and the gate interlayer dielectric layer.

The above mentioned data program method of a non-volatile memory device includes a method using Fowler-Nordheim (FN) tunneling or a method using hot electron injection. In the method using FN tunneling, a high voltage is applied to a control gate electrode of the non-volatile memory to apply a high electric field to a tunnel oxide layer, and electrons of a semiconductor substrate pass the tunnel oxide layer and are injected into a floating gate by the high electric field. In the method of hot electron injection, a high voltage is applied to a control gate electrode and a drain region of a non-volatile memory to inject a hot electron generated near the drain region to a floating gate through a tunnel oxide layer. Therefore, a high electric field should be applied to the tunnel oxide layer in both methods of the FN tunneling and the hot electron injection. In this case, a high coupling ratio (CR) is required in order to apply a high electric field to the tunnel oxide layer. However, if it is assumed that the parasitic capacitor values of the source and drain regions are very small and thus negligible, the coupling ratio depends on C_{ONO} and C_{TUN}, and such a coupling ratio (CR) is shown in the following formula I.

$${C}_{R} = \frac{{C}_{ONO}}{{C}_{TUN} + {C}_{ONO}} \qquad [ formula I ]$$

In this case C_{ONO} indicates capacitance between the control gate electrode and a floating gate, C_{TUN} indicates capacitance applied to the tunnel oxide layer interposed between the floating gate and the semiconductor substrate.

Therefore, in order to increase the coupling ratio (C_{R}), the surface area of the floating gate overlapped with the control gate electrode should be increased to increase the capacitance between the control gate electrode and the floating gate, i.e., C_{ONO}. However, when increasing the surface area of the floating gate, it is difficult to increase the integration degree of a flash memory device. Moreover, in recent years, with the high integration and miniaturization of semiconductor devices, the area where the capacitor will be formed should be further decreased. Thus, it is hard to increase the capacitance by increasing the area of the floating gate.

Particularly, as the height of the floating gate in a SoC product storing an EEPROM cell becomes larger, the height of the control gate becomes larger, thereby generating a problem that it is difficult to simultaneously pattern the logic gate and control gate of a peripheral circuit. In addition, as the distance between the bitline contact and a control gate in the EEPROM cell becomes shorter, which may lead to an electrical short-circuiting, more than a predetermined gap is required and thus the cell size is increased.

### SUMMARY OF THE INVENTION

The present invention is designed in consideration of the problems of the prior art, and therefore it is an object of the present invention to provide a method for manufacturing a non-volatile memory device which avoids affecting the height of a control gate as well as increasing a coupling ratio to obtain the capacitance by forming a trench in a cell region, forming a floating gate in a concave shape in the trench and making a dielectric film to cover the floating gate.

To achieve the above object, there is provided a method for manufacturing a non-volatile memory device, comprising the steps of: forming a first trench having a first depth on a silicon substrate of a peripheral circuit region, burying the same with a buried oxide film and planarizing the same; forming a second trench having a second depth on the silicon substrate of the cell region; carrying out channel ion implantation to the cell region, forming a tunnel oxide film in the second trench and depositing a floating gate material; forming a floating gate by etching the floating gate material; forming a source/drain junction in the cell region; forming wells in the peripheral circuit and cell regions and depositing a dielectric film; depositing a gate material while leaving the dielectric film only in the channel portion of the cell region; and forming a gate in the peripheral circuit region and a control gate in the cell region by etching the gate material.

According to the method for manufacturing a non-volatile memory device according to the present invention, it is possible to obtain the capacitance by forming a trench in a cell region, forming a floating gate in a concave shape in the trench and making a dielectric film to cover the floating gate, thusly it is also possible to reduce a cell size by decreasing the gap between a control gate and a bit line contact by decreasing the height of the control gate.

### BRIEF DESCRIPTION OF THE DRAWINGS

Other objects and aspects of the present invention will become apparent from the following description of embodiments with reference to the accompanying drawings in which:

FIGS. 1a to lj are sectional views sequentially showing a method for manufacturing a non-volatile memory device according to the present invention.

### DESCRIPTION OF THE PREFERRED EMBODIMENT

Hereinafter, a preferred embodiment of the present invention will be described in more detail referring to the drawings. In addition, the following embodiment is for illustration only, not intended to limit the scope of the invention.

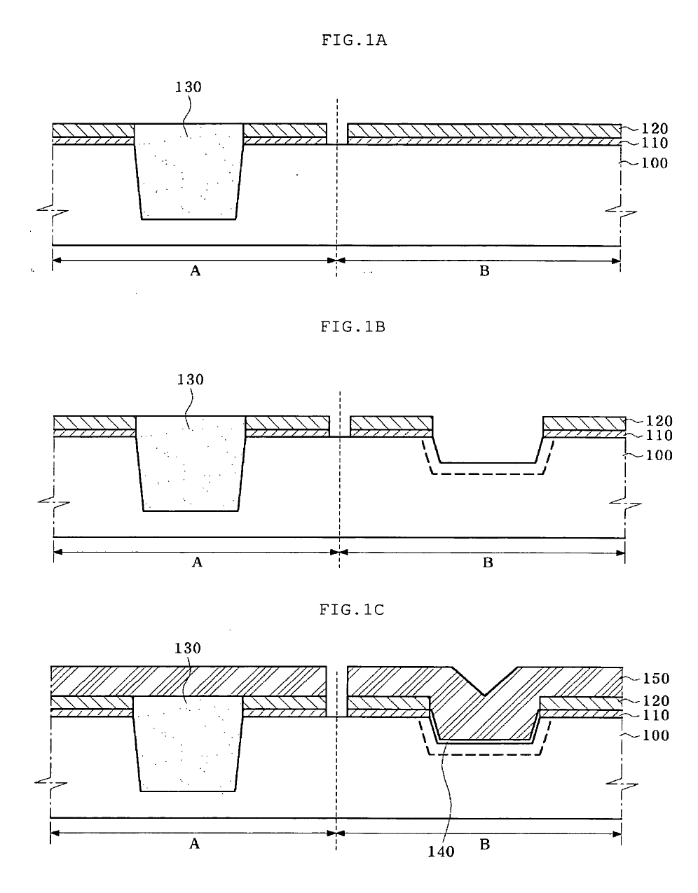

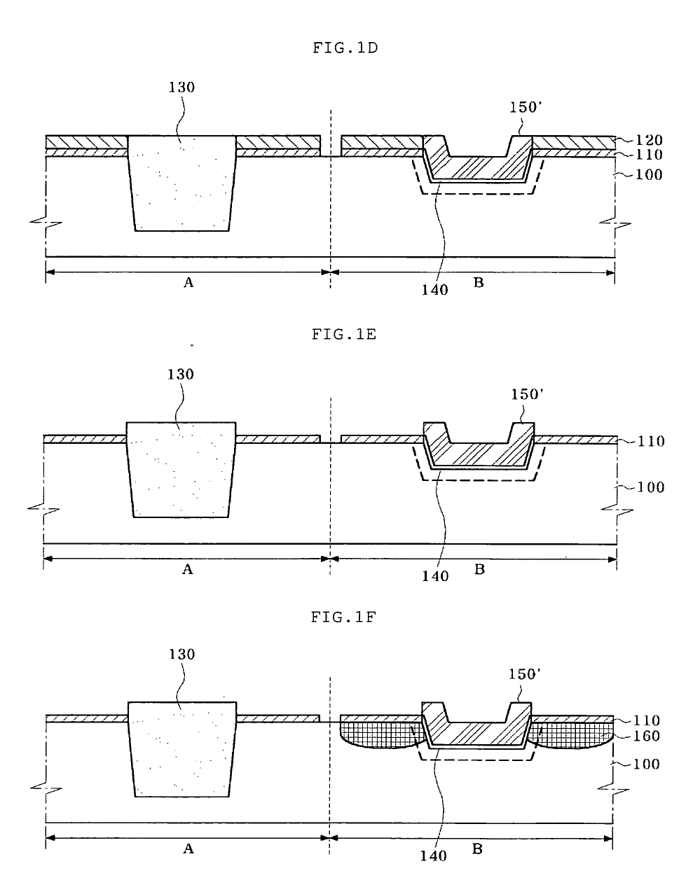

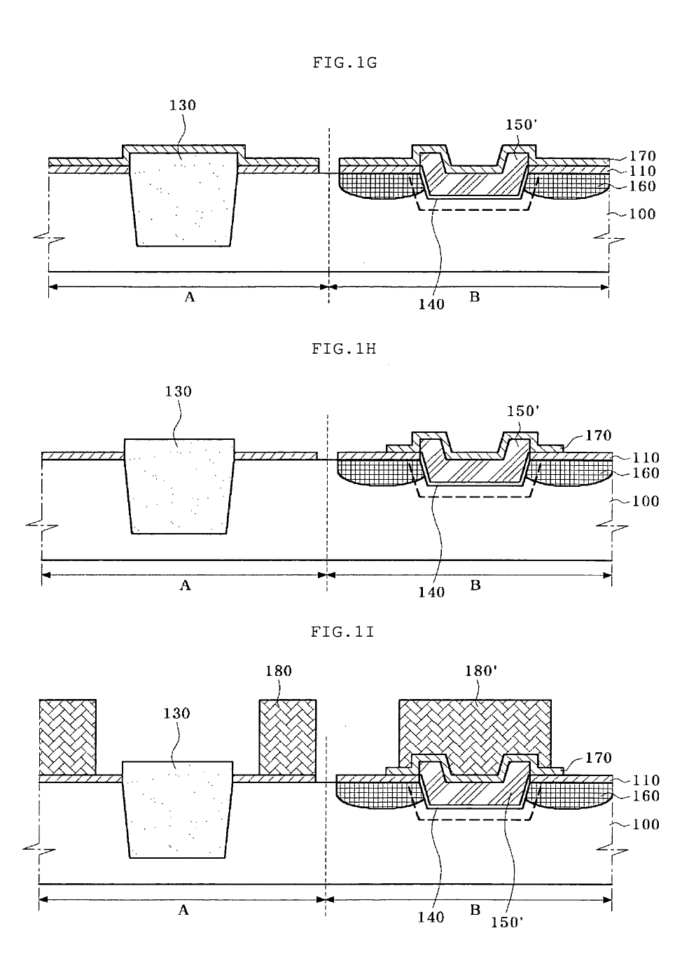

FIGS. 1a to 1j are sectional views sequentially showing a method for manufacturing a non-volatile memory device according to the present invention.

Firstly, as shown in FIG. 1a, a silicon oxide film 110 and a silicon nitride film 120 are sequentially deposited on a silicon substrate 100 divided into a peripheral circuit region A and cell region B, and then a first trench (not shown) having a first depth is formed on the silicon substrate 100 of the peripheral circuit region A by a photographic process and an etching process. Then, a buried oxide film 130, such as a HDP oxide film or USG (undoped silica glass) film, is deposited so that the first trench can be buried therein and planarized by a chemical mechanical polishing process.

Next, as shown in FIG. 1b, a second trench having a second depth is formed in the cell region B, and then channel ion implantation for adjusting the threshold voltage is carried out by using the silicon nitride film 120 as a barrier without a photographic process. At this time, it is preferred that the width of the second trench is more than half the deposition thickness of floating gate material, formed in next process.

Continuously, as shown in FIG. 1c, a tunnel oxide film 140 is formed in the cell region B and undoped polysilicon or amorphous silicon 150 is deposited. Then, as shown in FIG. 1d, a floating gate 150′ is formed only in the cell region by an etchback process.

After the formation of the floating gate 150′, as shown in FIG. 1e, the silicon nitride film 120 is removed. Then, as shown in FIG. 1f, an ion implantation process is performed to a source/drain 160 of the cell region B. At this time, the source/drain 160 of the cell region B is preferably formed at the same thickness as the trench of the second depth.

Next, though not shown, a twin well and a triple well required for peripheral circuit portion and cell operations are formed. As shown in FIG. 1g, a dielectric film 170, such as an ONO (oxide-nitride-oxide) dielectric film or a high dielectric film like Al₂O₃ or HfO₂, is deposited. Thereafter, as shown in FIG. 1h, the dielectric film 170 is made to remain only in the channel portion of the cell region B.

Afterwards, a gate material used as a gate electrode is deposited and photographic and etching processes are carried out to form a gate 180 in the peripheral circuit region A and the control gate 180′ in the cell region B as shown in FIG. 1i. At this time, the gate material is formed any one of polysilicon, amorphous silicon, and tungsten silicide.

According to the method for manufacturing a non-volatile memory device according to the present invention, it is possible to increase the coupling ratio by forming a trench in a cell region, forming a floating gate in a concave shape in the trench and making a dielectric film to cover the floating gate. Further, it is also possible to increase the margin of DOF (depth of focus) in the process of patterning the gate electrode of the peripheral circuit region and the control gate of the cell region by forming a floating gate in the trench.

As mentioned above, the present invention has a merit that the coupling ratio can be increased to improve the capacitance by forming a cell-floating gate in a concave shape in the trench.

Furthermore, the margin of DOF (depth of focus) can be increase upon patterning the gate electrode of the peripheral circuit region and the control gate of the cell region by forming a floating gate at a lower part of the trench. Also, the gap between the control gate and the bit line contact can be reduced by decreasing the height of the control gate to reduce the cell size, improving the integration degree.

1. A method for manufacturing a non-volatile memory device, comprising the steps of:
forming a first trench having a first depth on a silicon substrate of a peripheral circuit region, burying the same with a buried oxide film and planarizing the same;
forming a second trench having a second depth on the silicon substrate of the cell region;
carrying out channel ion implantation to the cell region, forming a tunnel oxide film in the second trench and depositing a floating gate material;
forming a floating gate by etching the floating gate material;
forming a source/drain junction in the cell region;
forming wells in the peripheral circuit and cell regions and depositing a dielectric film;
depositing a gate material while leaving the dielectric film only in the channel portion of the cell region; and
forming a gate in the peripheral circuit region and a control gate in the cell region by etching the gate material.

2. The method of claim 1, wherein the second trench is formed at a thickness half the deposition thickness of the floating gate material.

3. The method of claim 1, wherein the floating gate is formed of undoped polysilicon or amorphous silicon.

4. The method of claim 1, wherein the floating gate is formed in a concave shape in the second trench.

5. The method of claim 1, wherein the buried oxide film is a HDP oxide film or a USG (undoped silicate glass) film.

6. The method of claim 1, wherein the dielectric film is an ONO (oxide-nitride-oxide) dielectric film or a high dielectric film like Al₂O₃ or HfO₂.

7. The method of claim 1, wherein the dielectric film is overlapped with the control gate of the cell region by more than 0.01 to 0.1 μm.

8. The method of claim 1, wherein the gate material is formed any one of polysilicon, amorphous silicon, and tungsten silicide.

9. The method of claim 1, wherein the source/drain of the cell region is formed at the same thickness as the trench having the second depth.
